(19) United States
(12) Patent Application Publication
(10) Pub. No.: US 2011/0151357 A1
(43) Pub. Date: Jun. 23, 2011

(54) EXPOSURE DOSE MONITORING METHOD AND METHOD OF MANUFACTURING EXPOSURE DOSE MONITORING MASK

(76) Inventors: Yumi NAKAJIMA, Tokyo (JP); Takashi Sato, Fujisawa-shi (JP)

(21) Appl. No.: 12/969,308

(22) Filed: Dec. 15, 2010

(30) Foreign Application Priority Data
Dec. 15, 2009 (JP) 2009-284331

(51) Int. Cl. G03F 1/00; G03F 7/20

(52) U.S. Cl. 430/5; 430/325

(57) ABSTRACT

According to one embodiment, a monitoring pattern is transferred to a wafer by irradiation with EUV light by using a reflective mask including the monitoring pattern. Then, the line width of the monitoring pattern transferred to the wafer is measured, and a flare intensity distribution to be generated on the wafer is calculated in accordance with the reflecting region area of the mask and the layout direction of the monitoring pattern. After that, the measured line width of the monitoring pattern is corrected based on the calculated flare intensity distribution. Finally, the exposure dose of the monitoring pattern on the wafer is obtained from the corrected line width.

### CROSS-REFERENCE TO RELATED APPLICATIONS

This application is based upon and claims the benefit of priority from Japanese Patent Application No. 2009-284331, filed Dec. 15, 2009; the entire contents of which are incorporated herein by reference.

### FIELD

Embodiments described herein relate generally to an exposure dose monitoring method of monitoring an exposure dose, and a method of manufacturing an exposure dose monitoring mask for use in the exposure dose monitoring method.

### BACKGROUND

As the micropatterning of semiconductor devices advances, the line widths of circuit patterns are more and more reducing. The lithography technique meets this demand for line width reduction by shortening the wavelength of light for use in resist exposure. Using exposure light called EUV (Extreme Ultra Violet) light having a wavelength region centering around 13.5 nm from a generation of a pattern width of 30 nm or less is being examined. It is presumably possible by using the EUV light to reduce the pattern width and pattern pitch, which cannot be achieved by any conventional methods.

In micropattern exposure, it is essential to finely monitor and adjust an exposure dose. As an exposure dose monitoring method, a method of measuring, by a CCD image, the size of a resist pattern onto which an image of an exposure dose monitoring mask whose image size changes in accordance an exposure dose is transferred has been used.

It is, however, demonstrated that in EUV exposure, the shortness of a wavelength used or the structure of an optical system using a multilayered film mirror makes the influence of exposure flare greater than that in conventional excimer laser exposure. Therefore, a pattern formed by using the exposure dose monitoring mask is measured as not a dimension reflecting only the exposure light intensity but a dimension to which the flare influence is added. Furthermore, the mask 3D effect has a great influence on a reflective mask for use in EUV exposure. Since a monitoring pattern is also influenced by the mask 3D effect, the pattern is measured as different dimensions in a slit even when irradiated with the same exposure dose.

### BRIEF DESCRIPTION OF THE DRAWINGS

FIG. 1 is a view for explaining the shape of an exposure dose monitoring pattern and the principle of detection;

FIGS. 2A and 2B are views showing the way EUV exposure light enters mask patterns;

FIGS. 3A and 3B are views showing the positional relationship of an exposure slit to an exposure shot, and the dependence of a transfer pattern dimension on a position in the slit (a parallel pattern);

FIGS. 4A and 4B are views showing the positional relationship of an exposure slit to an exposure shot, and the dependence of a transfer pattern dimension on a position in the slit (a perpendicular pattern);

FIGS. 5A and 5B are views showing the layout of exposure dose monitoring patterns at different positions in a slit, and the results of calculations of dimensions on a wafer;

FIG. 6 is a flowchart for explaining an exposure dose monitoring method according to the first embodiment;

FIG. 7 is a view showing an example of the layout of monitoring patterns on a mask;

FIGS. 8A, 8B, and 8C are graphs respectively showing an uncorrected monitoring pattern dimension used in the first embodiment, a simulation result used in correction, and a corrected monitoring pattern dimension;

FIGS. 9A and 9B are views showing an intra-slit exposure dose monitoring pattern layout used in the second embodiment, and an exposure dose monitoring pattern dimension distribution;

FIG. 10 is a flowchart for explaining an exposure dose monitoring method according to the third embodiment;

FIG. 11 is a view showing pattern densities calculated from mask data of a chip exposed in the third embodiment;

FIG. 12 is a view showing a flare intensity distribution calculated from the pattern density distribution;

FIG. 13 is a graph showing exposure doses measured by using exposure dose monitoring patterns laid out in positions (1) to (12) shown in FIGS. 11 and 12;

FIG. 14 is a graph showing the results of correction obtained by subtracting, from the exposure doses measured in FIG. 13, exposure dose rises predicted by the flare intensity distribution calculated in FIG. 12;

FIG. 15 is a view for explaining the fourth embodiment, which shows an intra-shot exposure dose distribution measured by using exposure dose monitoring patterns;

FIGS. 16A and 16B are views showing an exposure slit shape and the movement of the slit in a shot when exposure is performed in the state shown in FIG. 15;

FIG. 17 is a view showing a slit shape adjusted based on the results measured in FIG. 15; and

FIG. 18 is a view showing an intra-shot exposure dose distribution obtained when exposure is performed using the slit shown in FIG. 17.

### DETAILED DESCRIPTION

In general, according to one embodiment, a monitoring pattern is transferred to a wafer by irradiation with EUV light by using a reflective mask including the monitoring pattern. Then, the line width of the monitoring pattern transferred to the wafer is measured, and a flare intensity distribution to be generated on the wafer is calculated in accordance with the reflecting region area of the mask and the layout direction of the monitoring pattern. After that, the measured line width of the monitoring pattern is corrected based on the calculated flare intensity distribution. Finally, the exposure dose of the monitoring pattern on the wafer is obtained from the corrected line width.

First, the basic principle of embodiments will be explained before the explanation of the embodiments.

The principle of exposure dose monitoring of the embodiments is as follows. That is, a monitoring pattern that changes the dimension on a wafer in accordance with the exposure dose are formed on a mask, and transferred to a wafer. The exposure dose is monitored by detecting the dimension of the monitoring pattern formed on the wafer.

The monitoring pattern is formed by arranging line patterns having different widths along one direction at a predetermined pitch that is not resolved under the illumination conditions of EUV light for use in exposure, such that the optical intensity of reflection to the EUV light symmetrically decreases outward from the central position. More specifically, patterns made of a light absorber are arranged along one direction at a predetermined pitch on a reflective mask substrate made of a multilayered film. The patterns made of the light absorber are rectangular patterns elongated in a direction perpendicular to the one direction. The rectangular patterns are arranged except for a predetermined distance in a central portion, and gradually widen outward from the central portion.

From a wavelength λ, numerical aperture NA, and stop amount σ of an exposure apparatus as a measurement target, a pitch P of the rectangular patterns except for the central portion is determined by

P≦λ/NA(1+σ)

In patterns smaller than this pitch, as shown in FIG. 1, diffracted light from a mask 11 goes out of the pupil of a projection lens 12. Accordingly, only the zero-order light arrives on a wafer 13. As a consequence, only the intensity of exposure light can be measured without any influence of focusing.

It is, however, demonstrated that in EUV exposure, the shortness of the wavelength used or the structure of an optical system using a multilayered film mirror makes the influence of exposure flare greater than that in excimer laser exposure. Therefore, patterns formed by using the exposure dose monitoring mask are measured as not dimensions reflecting only the exposure light intensity but dimensions to which the influence of the flare is added.

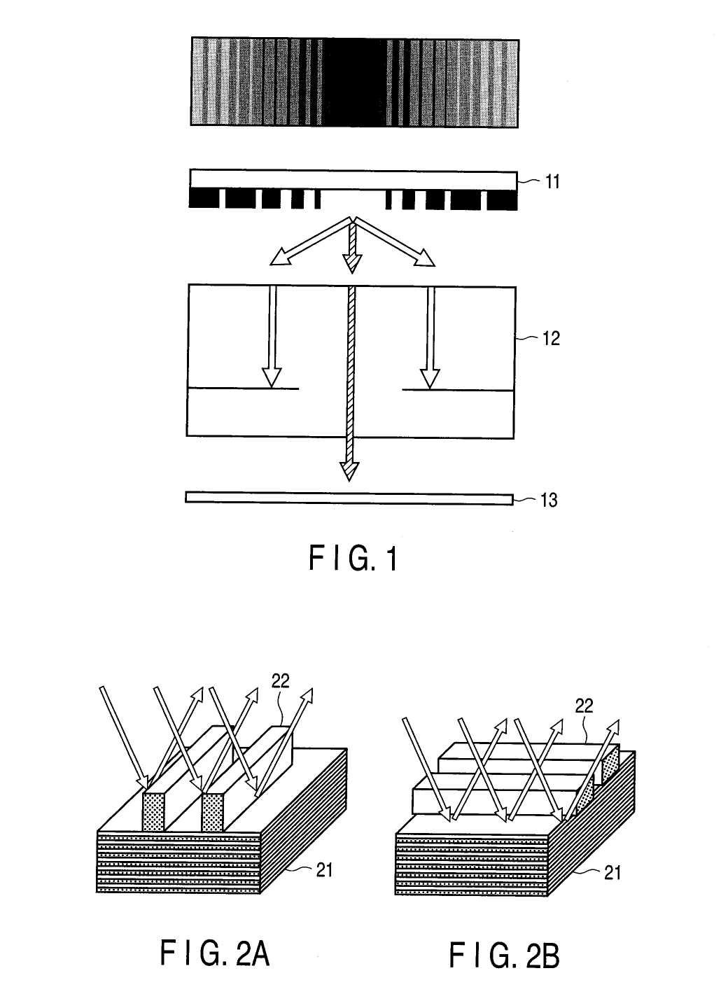

Furthermore, the mask 3D effect has a great influence on a reflective mask for use in EUV exposure. As shown in FIGS. 2A and 2B, the mask 3D effect includes the EUV light incident direction with respect to the mask pattern direction, and the shadowing effect obtained when the EUV light enters obliquely to the mask. Note that in FIGS. 2A and 2B, reference number 21 denotes a mask substrate having a multilayered film structure; and 22, mask patterns. In addition, since a point light source is used in EUV exposure, the degree of the influence of the shadowing effect changes in accordance with the position of an exposure region.

In EUV exposure, an entire shot is exposed by scanning an arcuate exposure region (slit) in the longitudinal direction of the shot. However, the shadowing effect changes along the slit direction, and this consequently generates a dimension distribution in the slit direction.

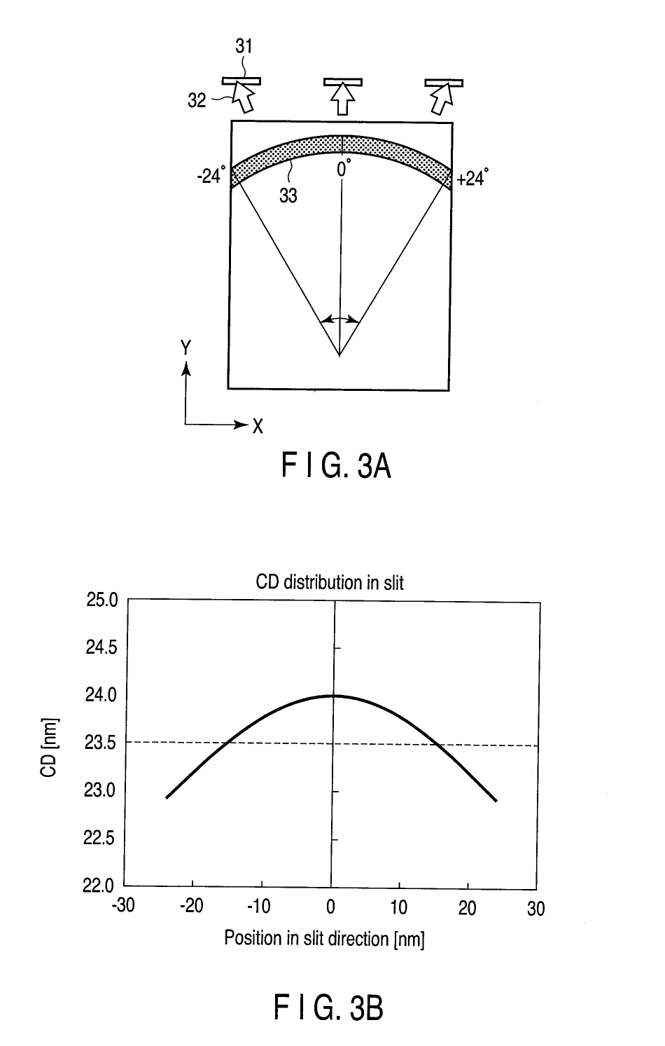

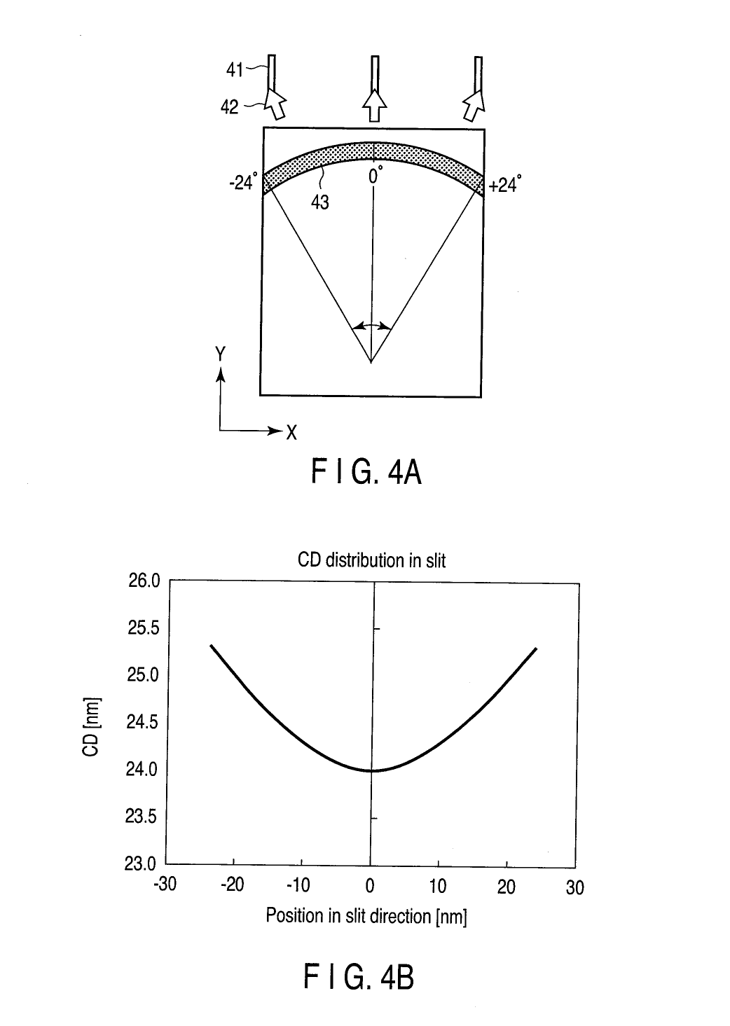

That is, as shown in FIG. 3A, for patterns 31 parallel to the slit direction (X-direction: the X direction perpendicular to the Y-direction is defined as the slit direction, although the slit is strictly an arc and hence does not completely match the X-direction) as shown in FIG. 3A, the CD value decreases as the angle of incidence increases as shown in FIG. 3B. In addition, for patterns 41 perpendicular to the slit direction (X-direction) as shown in FIG. 4A, the CD value increases as the angle of incidence increases as shown in FIG. 4B. Note that in FIGS. 3A and 4A, reference numbers 32 and 42 denote EUV light; and 33 and 43, exposure slits.

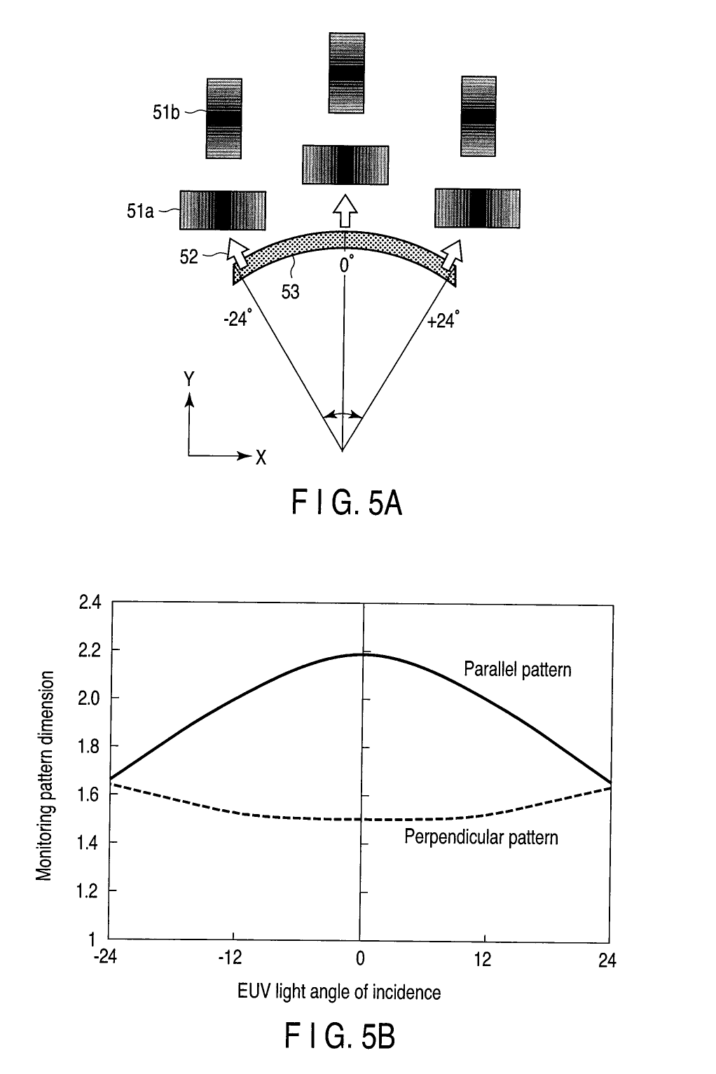

Also, an exposure dose monitoring pattern is influenced by the mask 3D effect, and measured as different dimensions in a slit even when irradiated with the same exposure dose. That is, as shown in FIG. 5A, the influence of the mask 3D effect changes in accordance with whether a monitor pattern is a parallel pattern or perpendicular pattern. That is, as shown in FIG. 5B, when the EUV angle of incidence is zero, the monitoring pattern dimension of a parallel pattern decreases, and that of a perpendicular pattern increases. Note that in FIG. 5A, reference number 51a denotes a monitoring pattern parallel to the slit direction (X-direction); 51b, a monitoring pattern perpendicular to the slit direction (X-direction); 52, EUV light; and 53, an exposure slit.

Accordingly, the following embodiments each propose a method of measuring only the exposure light intensity by obtaining and subtracting the influences of a flare and the mask 3D effect beforehand. Intra-mask monitoring pattern layouts that are not influenced by the mask 3D effect are also proposed. Details of the embodiments will be explained below.

### First Embodiment

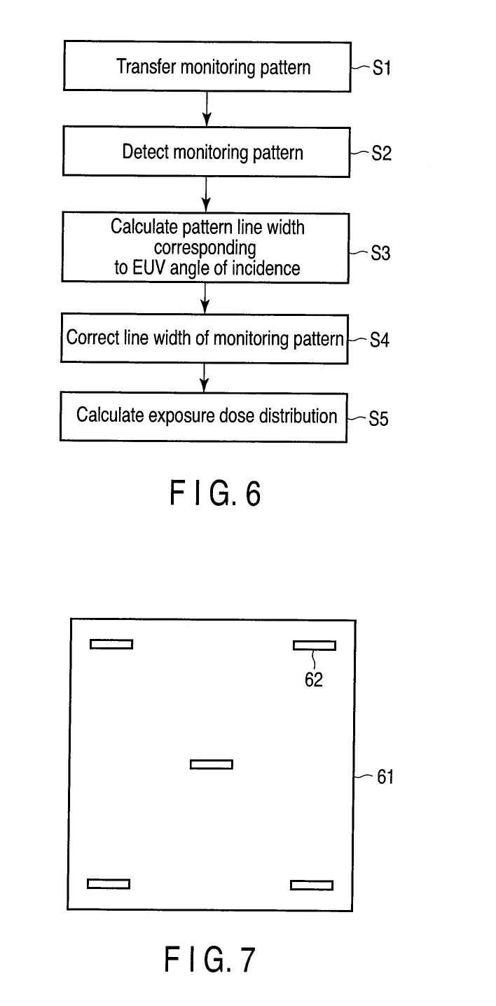

FIG. 6 is a flowchart for explaining an exposure dose monitoring method according to the first embodiment.

First, an exposure dose monitoring mask on which monitoring patterns are formed is irradiated with EUV light. The reflected light is guided to a wafer via a projection lens and the like, and an image of the reflected light is formed on the wafer, thereby transferring the monitoring patterns to a resist on the wafer (step S1). In the exposure dose monitoring mask as shown in FIG. 7, monitoring patterns 62 are formed in a plurality of portions of a mask substrate 61 having a size equivalent to one chip on the wafer. As shown in FIG. 1, each monitoring pattern 62 is formed by arranging line patterns having different widths along one direction at the same pitch.

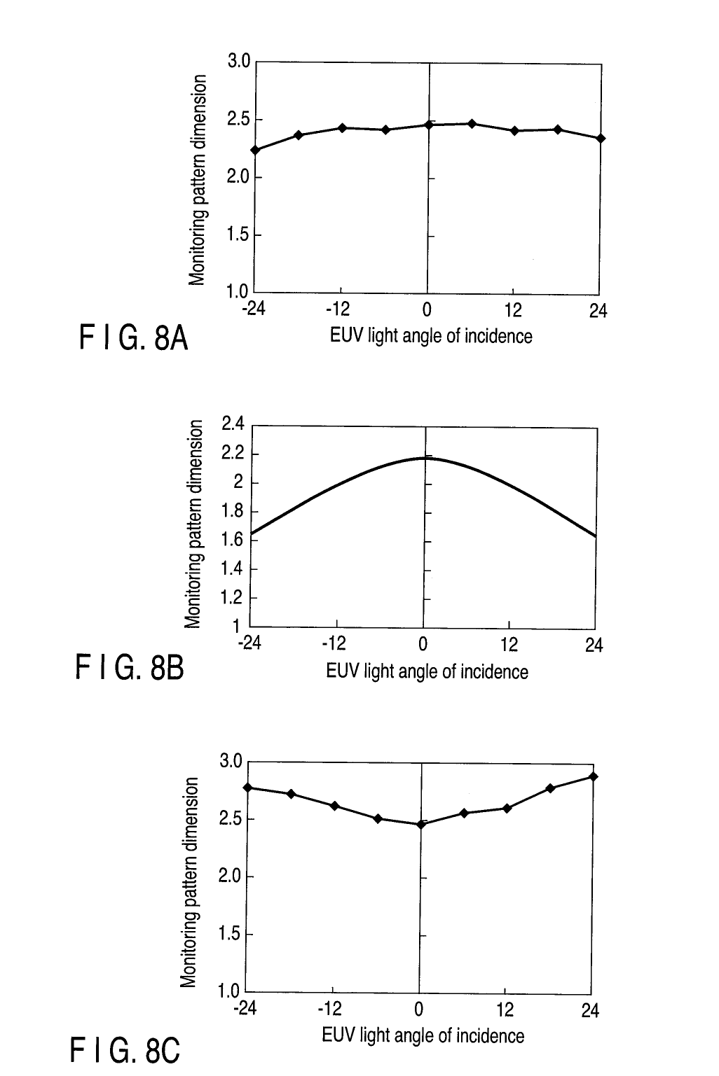

Subsequently, resist patterns are formed by developing the exposed wafer, and the dimensions of the resist patterns (monitoring patterns on the wafer) are detected by using an image sensing device such as a CCD (step S2). Consequently, a characteristic shown in FIG. 8A is obtained. That is, monitoring pattern dimensions (line widths) corresponding to the EUV angles of incidence are obtained.

On the other hand, those line widths of the monitoring patterns on the wafer, which correspond to the EUV angles of incidence on the wafer are precalculated (step S3). As a consequence, a characteristic shown in FIG. 8B is obtained. FIG. 8B shows monitoring pattern dimensions obtained by simulation and corresponding to positions in a slit. The dimension changes depending on a position in the slit, because the influence of the mask 3D effect is involved. The result is tabulated as correction data.

Then, the monitoring pattern line widths measured in step S2 are corrected based on the correction data obtained in step S3 (step S4). As a result, a characteristic shown in FIG. 8C is obtained. That is, monitoring pattern dimensions are obtained by correcting the influence of the mask 3D effect.

After that, an exposure dose distribution on the wafer is calculated from the line widths corrected in step S4 (step S5). The exposure dose can be obtained form the line width when the relationship between the line width and exposure dose is preobtained and pretabulated. Furthermore, the exposure dose distribution can be obtained from the line widths of monitoring patterns in a plurality of portions.

In this embodiment as described above, dimensional differences produced by the mask 3D effect are preobtained at different positions in a slit and corrected with respect to measured line widths. This makes it possible to accurately measure monitoring dimensions corresponding to only the exposure light intensity at different positions along the slit. Accordingly, it is possible to eliminate the influence of the mask 3D effect, and accurately measure the exposure dose distribution on a wafer.

### Second Embodiment

This embodiment improves the layout of monitoring patterns instead of correcting the measured dimensions of the monitoring patterns.

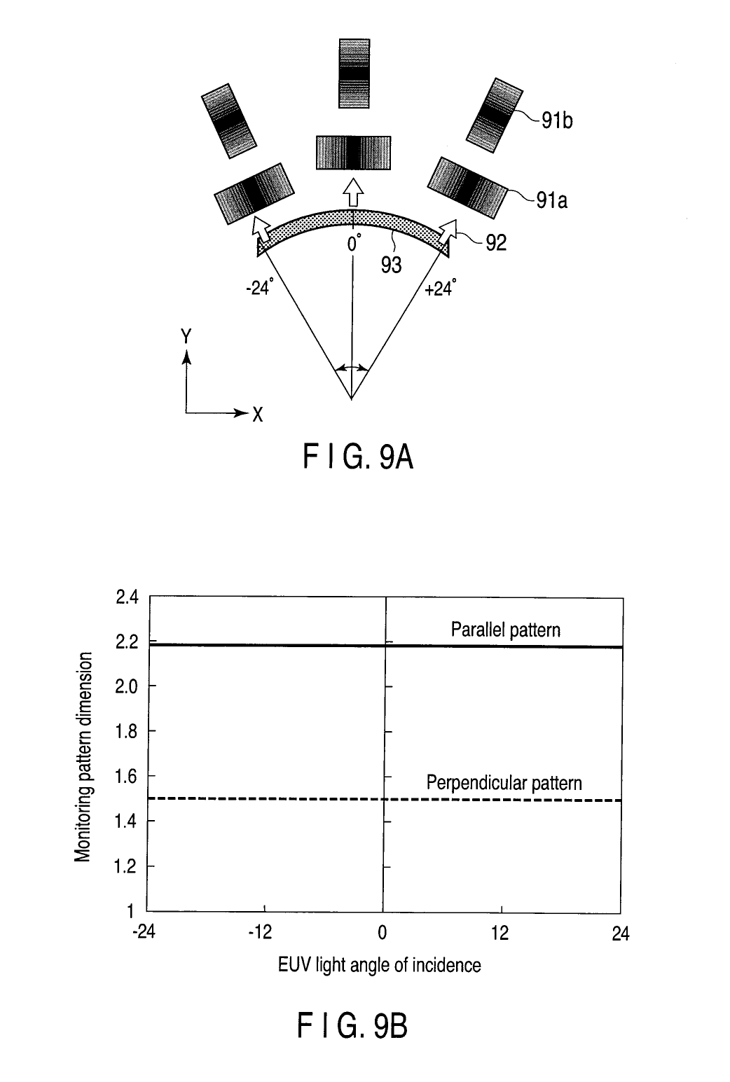

FIG. 9A shows the layout of intra-slit exposure dose monitoring patterns used in this embodiment. FIG. 9B shows an exposure dose monitoring pattern dimension distribution. Note that in FIG. 9A, reference number 91a denotes a monitoring pattern parallel to the slit direction (X-direction); 91b, a monitoring pattern perpendicular to the slit direction (X-direction); 92, EUV light; and 93, an exposure slit.

Conventionally, exposure dose monitoring patterns are laid out parallel or perpendicularly to the mask coordinate axis as shown in FIG. 5A described previously. In this case, EUV light emitted from a point light source enters the exposure dose monitoring patterns on a mask at different angles corresponding to positions in the slit. Consequently, the angle of light entering the exposure dose monitoring pattern changes from one position to another in the slit, and the corresponding pattern dimensions on the wafer are distributed as shown in the graph of FIG. 5B.

As shown in FIG. 9A, this embodiment improves this distribution by laying out patterns by rotating them through angles corresponding to the EUV light angles of incidence at different positions in the slit. In this case, the angle of incidence the EUV light with respect to the pattern direction of the monitoring pattern is made constant in the entire slit. As shown in FIG. 9B, therefore, the same dimension can be returned on a wafer for the same exposure dose, regardless of a position in the slit.

An electron beam lithography apparatus is generally used to form a monitoring pattern on an exposure dose monitoring mask. In this embodiment, when drawing a monitoring pattern on a mask by using the electron beam lithography apparatus, the direction of the monitoring pattern was matched with the direction of irradiation of EUV light. More specifically, monitoring patterns are laid out such that all the monitoring patterns have the same angle (e.g., parallel or perpendicular to the slit direction with respect to the pattern positions), with respect to the angle of incidence of EUV light on a mask when transferring the monitoring patterns to a wafer by irradiation with the EUV light.

To rotate a monitoring pattern in accordance with the EUV angle of incidence, a stencil mask having an opening corresponding to the monitoring pattern shape is formed, and rotated in accordance with a drawing position. It is also possible to give rotation information to monitoring pattern drawing data, instead of rotating the stencil mask.

In this embodiment as described above, monitoring patterns are laid out (rotated) in accordance with the EUV light incident directions corresponding to positions in a slit. This makes it possible to accurately measure monitoring dimensions corresponding to only the exposure light intensity at different positions along the slit. Accordingly, the exposure dose distribution on a wafer can be accurately measured as in the first embodiment described previously.

### Third Embodiment

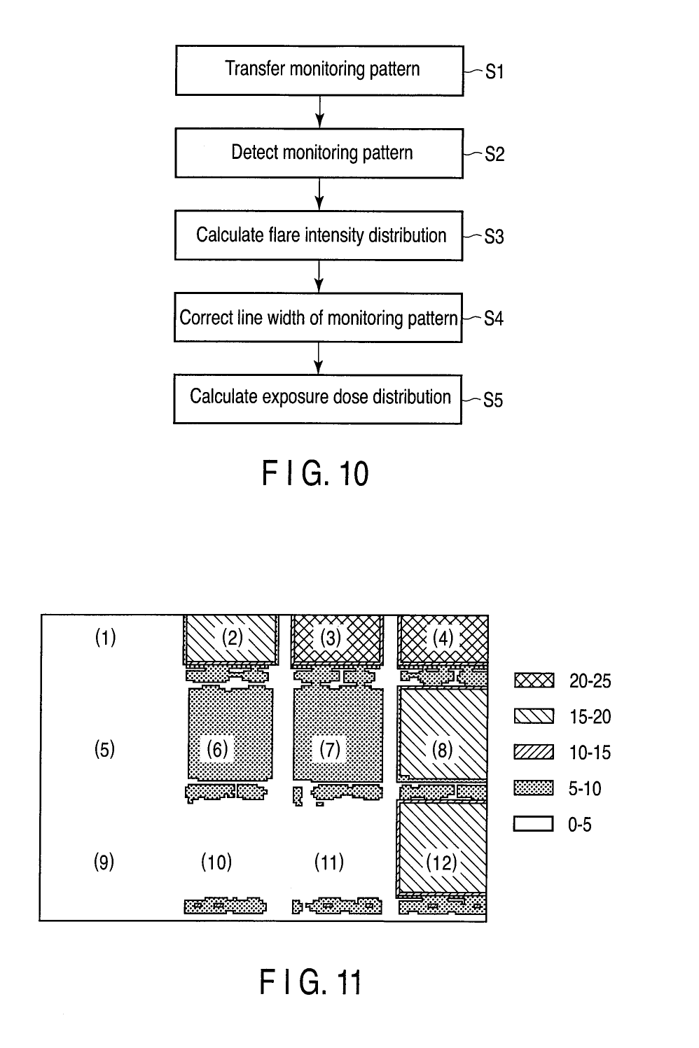

FIG. 10 is a flowchart for explaining an exposure dose monitoring method according to the third embodiment.

First, an exposure dose monitoring mask is irradiated with EUV light in the same manner as in the first embodiment. The reflected light from the mask is guided to a wafer via a lens and the like, and an image of the reflected light is formed on the wafer, thereby transferring monitoring patterns to the wafer (step S1). As in the first embodiment, the monitoring patterns are formed in a plurality of portions of the exposure dose monitoring mask.

Subsequently, resist patterns are formed by developing the exposed wafer, and the dimensions of the monitoring patterns are detected by using an image sensing device such as a CCD (step S2).

On the other hand, a flare intensity distribution generated on the wafer in accordance with the reflecting region area of the mask and the monitoring pattern layout direction is calculated (step S3). The result is tabulated as correction data.

Then, the measured line widths of the monitoring patterns are corrected by the precalculated flare intensity distribution (step S4). Consequently, monitoring of pattern dimensions from which the influence of exposure flare is eliminated is obtained.

After that, an exposure dose distribution on the wafer is calculated from the corrected line widths (step S5). The exposure dose can be obtained from the line width when the relationship between the line width and exposure dose is preobtained and pretabulated. Furthermore, the exposure dose distribution can be obtained from the line widths of monitoring patterns in a plurality of portions.

In this embodiment, the flare intensity distribution was calculated as follows.

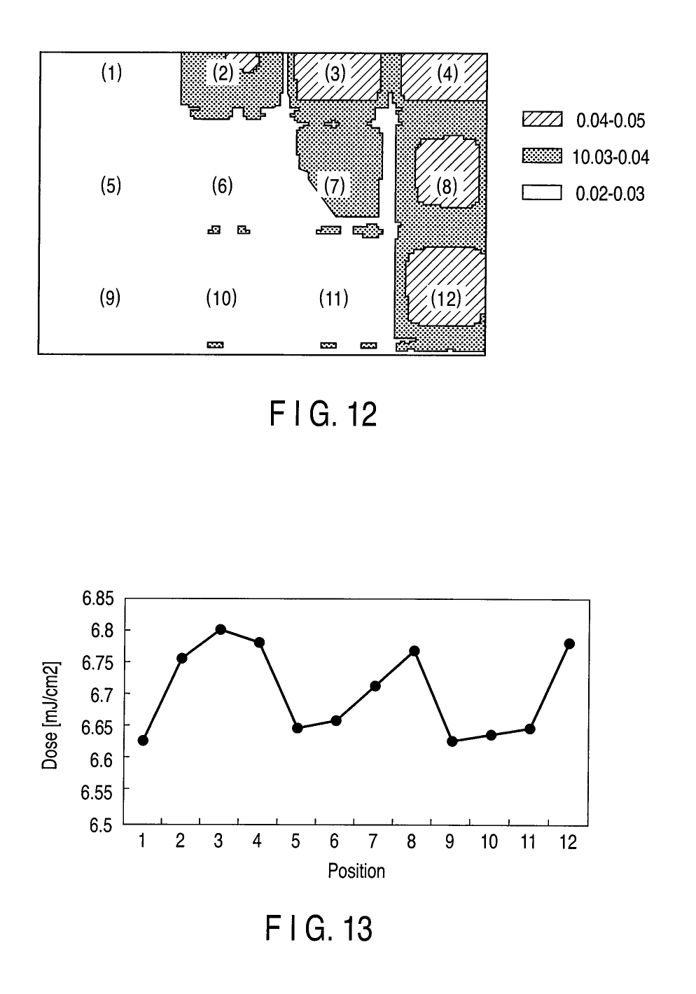

FIG. 11 shows pattern densities calculated from the mask data of a chip exposed in this embodiment. Referring to FIG. 11, the reflecting region density distribution on the mask is represented by steps of 5%. The higher the pattern density of a region, the larger the amount of EUV light with which the region is irradiated on the wafer. FIG. 12 shows a flare intensity distribution calculated from this pattern density distribution. In a region in which the pattern density is high and the amount of irradiation light is large, the flare intensity is high, and a flare close to 5% occurs.

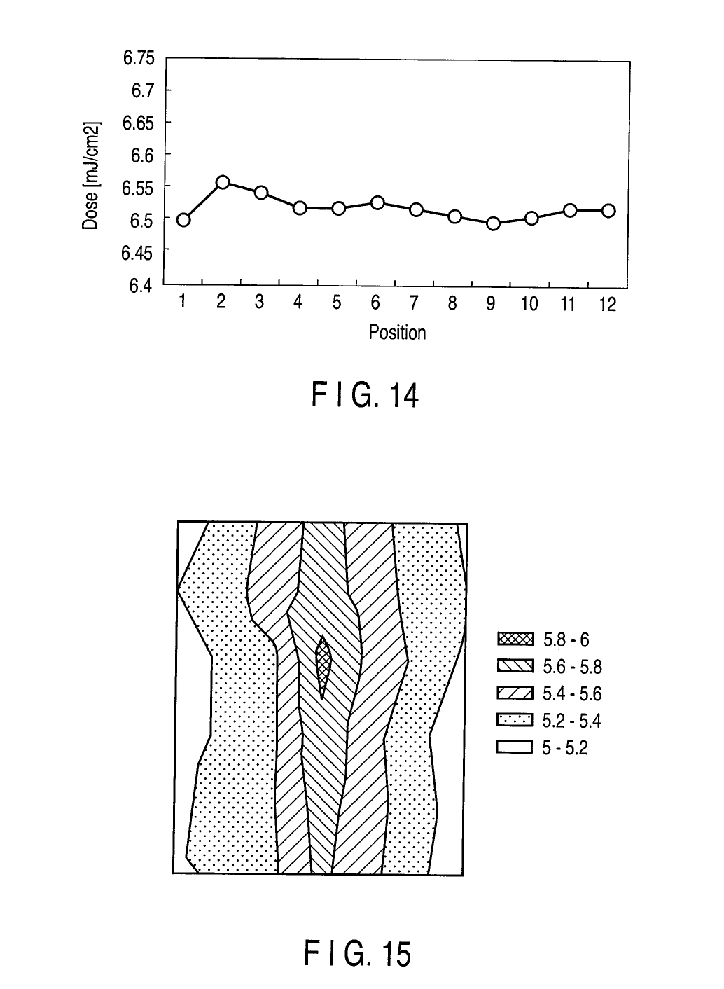

FIG. 13 shows exposure doses measured by using exposure dose monitoring patterns laid out in positions (1) to (12) shown in FIGS. 11 and 12. The exposure doses shown in FIG. 13 are influenced by the flare calculated in FIG. 12, and do not indicate the effective exposure dose distribution of the apparatus. Therefore, exposure dose rises predicted from the flare intensity distribution calculated in FIG. 12 are subtracted from the exposure doses measured in FIG. 13. FIG. 14 shows the result (correction result). The exposure dose distribution shown in FIG. 14 is the effective exposure dose distribution of the apparatus, which is not affected by flare.

In this embodiment as described above, a dimensional difference produced by a flare given to a monitoring pattern by a peripheral pattern is preobtained, and a measured value is corrected. This makes it possible to accurately measure monitoring dimensions by adding the influence of exposure flare. Accordingly, the exposure dose distribution on a wafer can be accurately measured as in the previous embodiments.

### Fourth Embodiment

In this embodiment, a method of uniformizing an exposure dose distribution based on the exposure dose distribution on a wafer measured in the first, second, or third embodiment described above will be explained.

Assume that FIG. 15 shows an exposure dose distribution measured on the entire surface of a shot by the exposure dose monitoring method used in the first, second, or third embodiment. The observed exposure dose is highest in the center of the shot, and low at the right and left ends. This is so because the intra-slit exposure dose distribution of an exposure apparatus is nonuniform.

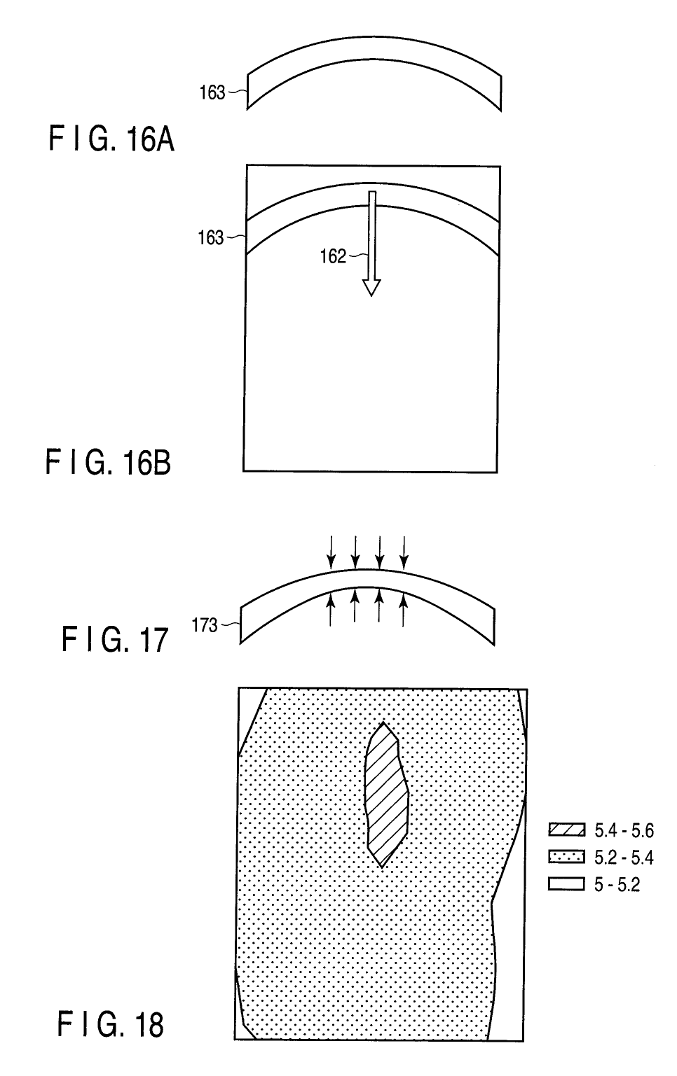

FIG. 16A shows a slit of the exposure apparatus. FIG. 16B shows the way the slit scans a shot and exposes the entire shot. In FIGS. 16A and 16B, reference number 162 denotes EUV light; and 163, an exposure slit. The exposure dose distribution after scanning becomes nonuniform as shown in FIG. 15 probably because the exposure dose in the central portion of the slit is higher than those at the end portions of the slit.

Accordingly, exposure was performed by mechanically deforming the slit shape as shown in FIG. 17 based on the exposure dose distribution measured in FIG. 15. The purpose of the deformation is to decrease the width of a slit 173 forming a high-exposure-dose portion as measured in FIG. 15, thereby decreasing exposure doses accumulated during scanning.

FIG. 18 shows an exposure dose distribution measured again by performing exposure by using the slit 173 narrowed in the central portion based on the measured exposure dose distribution shown in FIG. 15. As shown in FIG. 18, the variation in exposure dose distribution is much smaller than that shown in FIG. 15. That is, it was possible to improve the uniformity of the exposure doses in a shot.

As described above, this embodiment can improve the uniformity of the exposure doses in a shot by correcting the slit shape of an exposure apparatus based on the exposure dose distribution measured by using the exposure dose monitoring method of the first, second, or third embodiment. Accordingly, this embodiment can help increase the dimensional accuracy of a transfer pattern by using this exposure apparatus.

### (Modifications)

Note that the present invention is not limited to each embodiment described above. The structure of the exposure dose monitoring mask is not limited to that shown in FIGS. 1, 2A, and 2B, and can be any structure as long as the dimension of a pattern to be transferred to a wafer changes in accordance with the exposure dose. In addition, monitoring patterns on a wafer need not be measured by a CCD image sensing device, and can be measured by any device capable of measuring the dimensions of monitoring patterns on a wafer.

Furthermore, although flare correction, mask 3D effect correction, and the like are independently performed in the embodiments, these processes can also be combined. That is, it is also possible to effectively combine the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An exposure dose monitoring method comprising:
Transferring a monitoring pattern to a wafer by irradiation with EUV light by using a reflective mask including the monitoring pattern, the monitoring pattern being a pattern that causes different pattern dimensions on the wafer in accordance with an exposure dose;
measuring a line width of the monitoring pattern transferred to the wafer;
calculating a flare intensity distribution to be generated on the wafer, in accordance with a reflecting region area of the mask and a layout direction of the monitoring pattern;
correcting the measured line width of the monitoring pattern based on the calculated flare intensity distribution; and
obtaining an exposure dose of the monitoring pattern on the wafer from the corrected line width.

2. The method according to claim 1, wherein the monitoring pattern is formed in a plurality of portions on the mask, and an exposure dose distribution on the wafer is obtained by obtaining exposure doses of a plurality of monitoring patterns transferred to the wafer.

3. The method according to claim 1, wherein the monitoring pattern is formed by arranging line patterns having different widths along one direction at a predetermined pitch which is not resolved under illumination conditions of EUV light for use in exposure, such that an optical intensity of reflection to the EUV light decreases outward from a central position.

4. The method according to claim 1, wherein the monitoring patterns comprise a first group formed along one direction, and a second group formed along a direction perpendicular to the one direction.

5. The method according to claim 1, wherein the transferring of the monitoring pattern on the mask to the wafer comprises transferring the monitoring pattern to a resist on the wafer.

6. The method according to claim 5, wherein the measuring the line width of the monitoring pattern comprises detecting a dimension of the pattern of the resist by using an image sensing device.

7. The method according to claim 1, wherein instead of calculating the flare intensity distribution, a relationship between the reflecting region area of the mask, the layout direction of the monitoring pattern, and the flare intensity distribution generated on the wafer is preobtained and pretabulated.

8. The method according to claim 1, wherein the obtaining the exposure dose of the monitoring pattern on the wafer from the corrected line width comprises preobtaining and pretabulating a relationship between the line width and the exposure dose, and obtaining the exposure dose from the line width based on the table.

9. An exposure dose monitoring method comprising:
transferring, to a wafer, a monitoring pattern whose pattern dimension to be transferred to a wafer changes in accordance with an exposure dose, by irradiation with EUV light by using a reflective mask including the monitoring pattern;
measuring a line width of the monitoring pattern transferred to the wafer;
precalculating a line width of the monitoring pattern on the wafer, which corresponds to an angle of incidence of the EUV light on the mask;
correcting the measured line width of the monitoring pattern based on the calculated line width corresponding to the angle of incidence; and
obtaining an exposure dose of the monitoring pattern on the wafer from the corrected line width.

10. The method according to claim 9, wherein the monitoring pattern is formed in a plurality of portions on the mask, and an exposure dose distribution on the wafer is obtained by obtaining exposure doses of a plurality of monitoring patterns transferred to the wafer.

11. The method according to claim 9, wherein the monitoring pattern is formed by arranging line patterns having different widths along one direction at a predetermined pitch which is not resolved under illumination conditions of EUV light for use in exposure, such that an optical intensity of reflection to the EUV light decreases outward from a central position.

12. The method according to claim 9, wherein the monitoring patterns comprise a first group formed along one direction, and a second group formed along a direction perpendicular to the one direction.

13. The method according to claim 9, wherein the transferring of the monitoring pattern on the mask to the wafer comprises transferring the monitoring pattern to a resist on the wafer.

14. The method according to claim 13, wherein the measuring the line width of the monitoring pattern comprises detecting a dimension of the pattern of the resist by using an image sensing device.

15. The method according to claim 9, wherein instead of calculating the line width of the monitoring pattern on the wafer, which corresponds to the angle of incidence of the EUV light on the wafer, a relationship between the angle of incidence of the EUV light on the mask and the line width of the monitoring pattern on the wafer is pretabulated.

16. The method according to claim 9, wherein the obtaining the exposure dose of the monitoring pattern on the wafer from the corrected line width comprises preobtaining and pretabulating a relationship between the line width and the exposure dose, and obtaining the exposure dose from the line width based on the table.

17. A method of manufacturing an reflective exposure dose monitoring mask including a monitoring pattern whose pattern dimension to be transferred to a wafer changes in accordance with an exposure dose, comprising:
laying out monitoring patterns made of an absorber which absorbs EUV light in a plurality of portions on a substrate which reflects the EUV light, such that the monitoring patterns make the same angle with respect to an angle of incidence of the EUV light on the mask when transferring the monitoring patterns by irradiation with the EUV light.

18. The method according to claim 17, wherein the monitoring pattern is drawn on the substrate by electron beam lithography by using and rotating, in accordance with a drawing position, a stencil mask having an opening corresponding to a shape of the monitoring pattern.
